(19) United States
(12) Patent Application Publication
(10) Pub. No.: US 2024/0019914 A1
(43) Pub. Date: Jan. 18, 2024

(54) LAPTOP BLOWER USING AC IONIC WIND PRINCIPLES

(71) Applicant: Intel Corporation, Santa Clara, CA (US)

(72) Inventors: Krishnendu Saha, Bangalore (IN); Pawan Shiv Vadakattu, Bangalore (IN); Samarth Alva, Bangalore (IN); Bala Subramanya, Bangalore (IN)

(73) Assignee: Intel Corporation, Santa Clara, CA (US)

(21) Appl. No.: 18/477,881

(22) Filed: Sep. 29, 2023

(51) Int. Cl. G06F 1/20; H05K 7/20; H02M 7/5387

(52) U.S. Cl. CPC G06F 1/20; H05K 7/20172; H02M 7/5387

(57) ABSTRACT

In one embodiment, an AC ionic blower apparatus includes a housing defining a hole through the housing, a first electrode formed around the hole, a second electrode formed around the hole, and a dielectric material between the first electrode and the second electrode. The center of the second electrode is offset from the center of the first electrode.

### BACKGROUND

There has been a limit to delivering high performance processing in thin and light computing devices, e.g., laptop computing devices having a base thickness of approximately 8-10 mm or lower. Meanwhile, the power densities of computing platform components included in these devices continue to increase. Because of these higher power densities, component temperatures (and hence, local skin temperatures of the components) are increasing as well and in some cases, reaching beyond threshold values.

### BRIEF DESCRIPTION OF THE DRAWINGS

FIG. 1 illustrates an example system for inducing airflow using an alternating current (AC) voltage source in accordance with embodiments herein.

FIGS. 2A-2E illustrate an example AC ionic blower apparatus in accordance with embodiments herein.

FIG. 3 illustrates different electrode shapes that may be implemented within an AC ionic blower apparatus in accordance with embodiments herein.

FIGS. 4A-4D illustrate other example AC ionic blower apparatuses in accordance with embodiments herein.

FIG. 5 illustrates a block diagram of example driving circuitry for an AC ionic blower in accordance with embodiments herein.

FIGS. 6A-6B illustrate an example computing device in which aspects of the present disclosure may be incorporated.

FIG. 7 illustrates an example block diagram of a computing device in which aspects of the present disclosure may be incorporated.

FIG. 8 is a block diagram of computing device components which may be included in a mobile computing device incorporating aspects of the present disclosure.

FIG. 9 is a block diagram of an exemplary processor unit that can execute instructions.

### DETAILED DESCRIPTION

In the following description, specific details are set forth, but aspects of the technologies described herein may be practiced without these specific details. Well-known circuits, structures, and techniques have not been shown in detail to avoid obscuring an understanding of this description. “An embodiment,” “various embodiments,” “some embodiments,” and the like may include features, structures, or characteristics, but not every embodiment necessarily includes the particular features, structures, or characteristics.

Some embodiments may have some, all, or none of the features described for other embodiments. “First,” “second,” “third,” and the like describe a common object and indicate different instances of like objects being referred to. Such adjectives do not imply objects so described must be in a given sequence, either temporally or spatially, in ranking, or any other manner. “Connected” may indicate elements are in direct physical or electrical contact with each other and “coupled” may indicate elements co-operate or interact with each other, but they may or may not be in direct physical or electrical contact. Terms modified by the word “substantially” include arrangements, orientations, spacings, or positions that vary slightly from the meaning of the unmodified term. For example, description of a lid of a mobile computing device that can rotate to substantially 360 degrees with respect to a base of the mobile computing includes lids that can rotate to within several degrees of 360 degrees with respect to a device base.

The description may use the phrases “in an embodiment,” “in embodiments,” “in some embodiments,” and/or “in various embodiments,” each of which may refer to one or more of the same or different embodiments. Furthermore, the terms “comprising,” “including,” “having,” and the like, as used with respect to aspects of the present disclosure, are synonymous.

Reference is now made to the drawings, which are not necessarily drawn to scale, wherein similar or same numbers may be used to designate same or similar parts in different figures. The use of similar or same numbers in different figures does not mean all figures including similar or same numbers constitute a single or same embodiment. Like numerals having different letter suffixes may represent different instances of similar components. The drawings illustrate generally, by way of example, but not by way of limitation, various embodiments discussed in the present document.

In the following description, for purposes of explanation, numerous specific details are set forth in order to provide a thorough understanding thereof. It may be evident, however, that the novel embodiments can be practiced without these specific details. In other instances, well known structures and devices are shown in block diagram form in order to facilitate a description thereof. The intention is to cover all modifications, equivalents, and alternatives within the scope of the claims. While aspects of the present disclosure may be used in any suitable type of computing device, the examples below describe example mobile computing devices/environments in which aspects of the present disclosure can be implemented.

Aspects of the present disclosure may provide higher cooling capabilities in computing systems, such as thin and light computing systems (e.g., laptop devices) by inducing air flow without the acoustic impact of a fan or other physical air mover. There exists some fanless systems currently; however, such systems present issues such as, for example, reliability and dust accumulation on electrodes, which can negatively affect the operation of the device over time. In embodiments herein, a relatively large alternating current (AC) voltage may be used with a suitable electrode arrangement to induce air flow while avoiding the dust accumulation and reliability issues seen with current fanless solutions. Thus, some embodiments may operate at approximately sub-ambient level acoustic level (e.g., less than 12 dBA) while also providing adequate air flow to cool 15-20 W of computing system power.

In particular, embodiments herein may utilize ionic wind principles whereby air flow is induced by two offset electrodes separated by a dielectric material and driven with a relatively high AC voltage. In certain embodiments, one of the electrodes may be exposed to the air and may receive a high voltage AC signal from a power supply, while the other electrode may be embedded within a housing or inside the dielectric material and be connected to the ground signal of the AC power supply. Since only one electrode is exposed to air in such embodiments (and due to the shape of the electrode), it may be more reliable with respect dust accumulation, humidity, and high volume manufacturing (HVM) as compared with current fanless systems.

Aspects of the present disclosure may provide one or more of the following advantages over current blower-based cooling systems for computing device. As one example, embodiments herein have no moving components and allow for operation at ambient level acoustic level (e.g., ˜12 dBA or below) while also providing adequate PQ to cool ˜20 W of system base power. In addition, conventional fan systems require a circular or square space in the motherboard and take up a large amount of space inside a laptop computing device, whereas with embodiments herein may require far less space (which can in turn enable space for higher battery capacities or other features). Further, without the large fan cutout space needed, higher speed input/output (IQ) signals can be achieved as routing lengths may be shortened. Moreover, since embodiments herein have no moving parts, they may be much more reliable than typical fan-based systems.

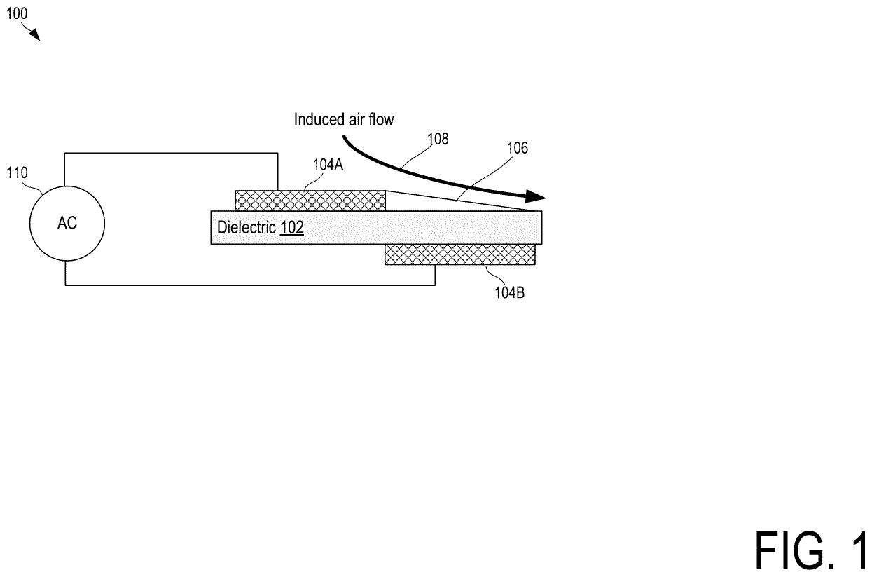

FIG. 1 illustrates an example system 100 for inducing airflow using an alternating current (AC) voltage source in accordance with embodiments herein. The example system 100 and embodiments herein utilize ionic wind principles to operate, which is a phenomenon caused by two electrodes kept at high AC voltage difference (e.g., 5-10 kV), which ionizes air between the electrodes. Movement of ions from one electrode to the other creates a movement of air alongside the ions.

Referring to FIG. 1, this is shown by the AC voltage source 110 being connected to the electrodes 104A, 104B, which are separated by a dielectric material 102. In addition, as shown, the electrodes 104A, 104B are spaced apart in the lateral direction so that their centers are offset from one another. In the example shown, the right side of the top electrode 104A is substantially aligned with the left side of the bottom electrode 104B. When the AC voltage is applied to the electrodes, positive and negative ions are produced in both cycles of the AC signal which moves towards the bottom electrode 104B. Due to the dielectric material 102 present between the electrodes 104 and the offset/lateral distance between the electrodes 104, ions flow in the lateral directions and create an induced air flow 108 of neutral air particles along with them. This may also be known as dielectric-barrier discharge (DBD) plasma (106 in the example shown).

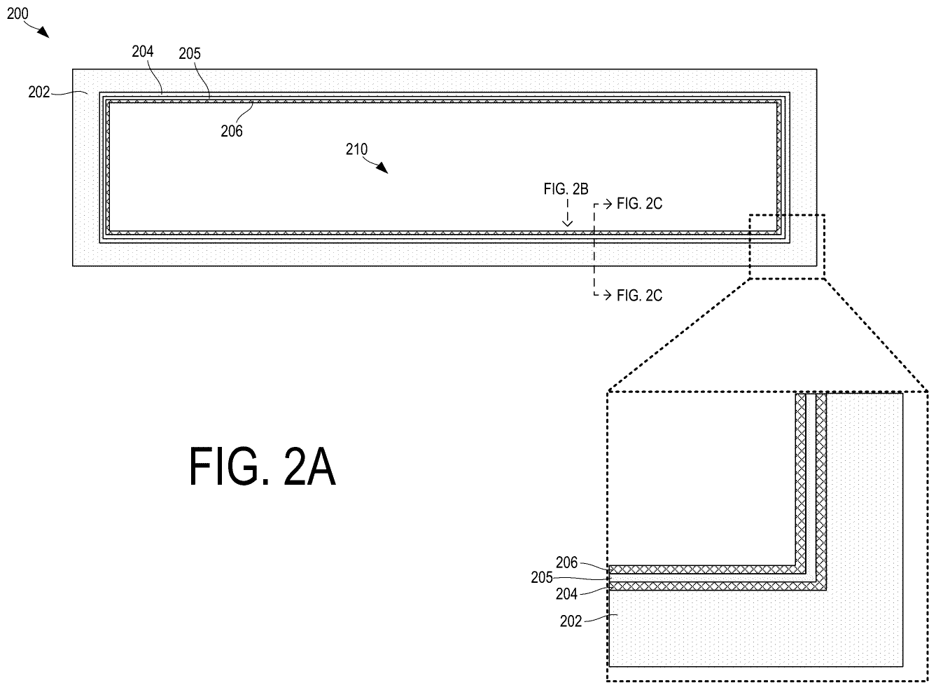

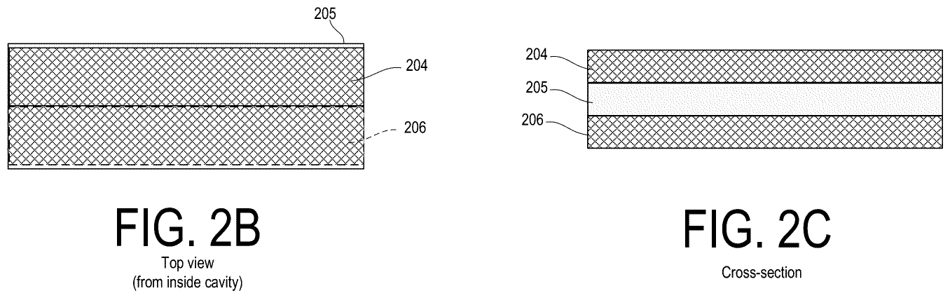

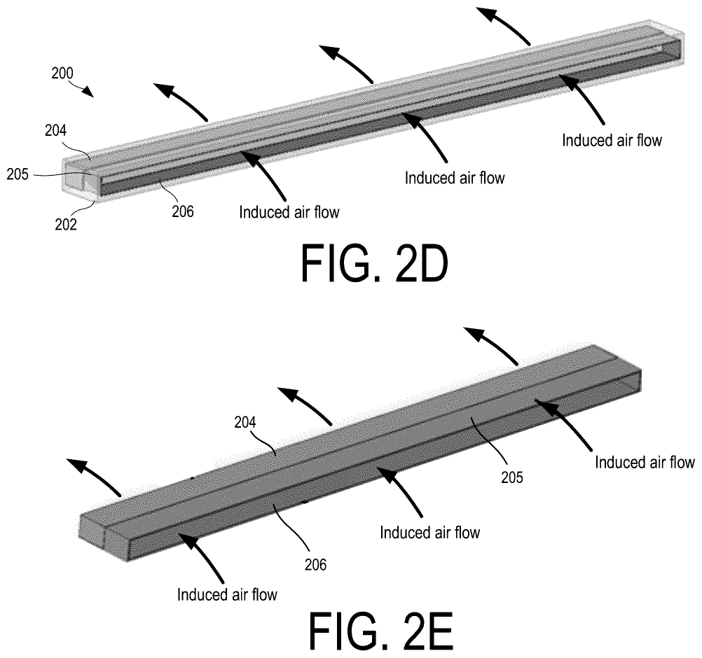

FIGS. 2A-2E illustrate an example AC ionic blower apparatus 200 in accordance with embodiments herein. The example blower apparatus 200 includes a housing 202, which can be made of or include a plastic or similar material (e.g., Teflon, Kapton, Peek, etc.), with an electrode structure similar to that shown in FIG. 1 along an inner surface of a hole 210 defined by the housing 202. The hole 210 in the example shown is rectangular; however, other embodiments may implement holes 210 with different shapes, e.g., oval, circular, etc. The electrode structure of the blower includes a first electrode 204 and a second electrode 206 separated by a dielectric layer 205. In other embodiments, the electrode 204 may be embedded within the housing 202, which may be made of a suitable dielectric material for inducing AC ionic wind and thus act as the dielectric layer 205, with the electrode 206 being formed on the surface of the hole 210 within the housing 202. The electrodes 204, 206 can be made, for example, through electroplating/coating of copper on a dielectric substrate, or by bonding copper tape on either side of a dielectric substrate (whose thickness may be between 0-1 mm, e.g., approximately 0.1 mm).

The dimensions of the apparatus 200 may be dictated by the use case. In thin computing devices, for example, the inside height of the hole may be 3-4 mm, with the housing thickness being between 0.5-1.5 mm (e.g., approximately 0.8 mm). The length of the housing 202 may be any suitable length. In some embodiments, the length may be 150 mm, causing the overall electrode length to be approximately 300 mm (i.e., top side 150 mm+bottom side 150 mm+side heights of a few mm each). Such dimensions may provide sufficient flow for cooling a system-on-chip (SoC) running at approximately 15-20 W.

FIGS. 2D-2E illustrate perspective views of the AC ionic blower apparatus of FIGS. 2A-2C. In particular, FIG. 2D illustrates the entire apparatus 200 with the housing 202, while FIG. 2E illustrates the electrode structure without also showing the housing 202, for clarity. As shown in these examples, the induced air flow may come from the side of the apparatus 200 on which the exposed electrode 206 is formed, and travel through the hole 210 formed by the housing 202.

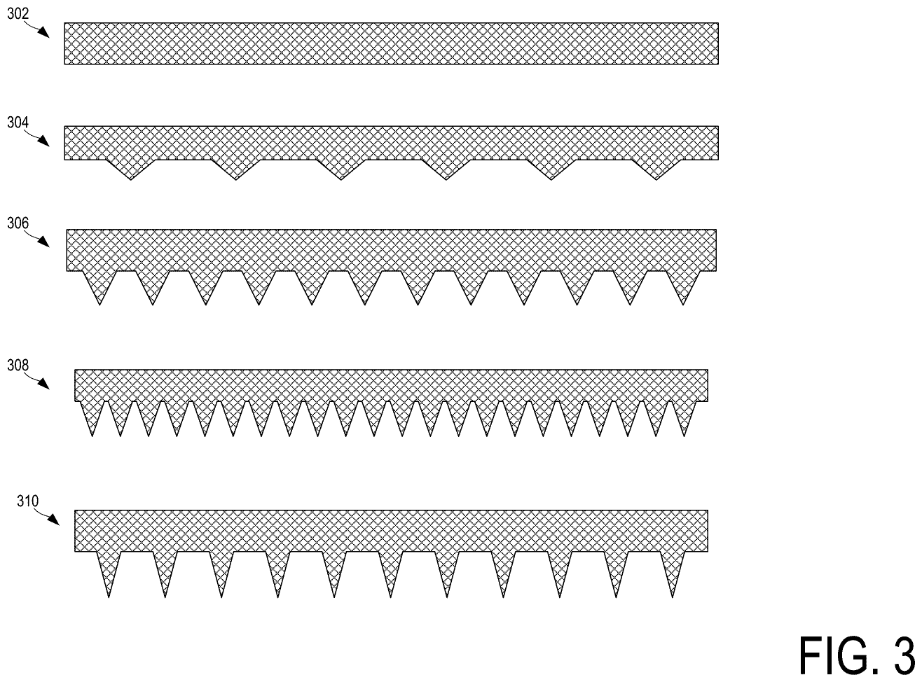

FIG. 3 illustrates different electrode shapes that may be implemented within an AC ionic blower apparatus in accordance with embodiments herein. The example electrode 302 is rectangular in the same way that the electrodes of the apparatus 200 are. The flow rate of the apparatus 200 (as well as other apparatuses as described herein) may scale with the size of the electrode length. For a rectangular electrode configuration like that shown in FIGS. 2A-2E, a minimum scaled flow rate may be expected to be, for example, between 1.5-2 CFM (cubic feet per minute), which may be sufficient to cool up to 17 W SoC power. In some embodiments, other electrode shapes may be implemented to increase air flow beyond these figures. For instance, the electrode designs 304-310 include saw tooth shapes that may allow for higher flow rates in the apparatus 200 than the figures above, allowing for additional cooling capabilities, e.g., for higher power SoCs.

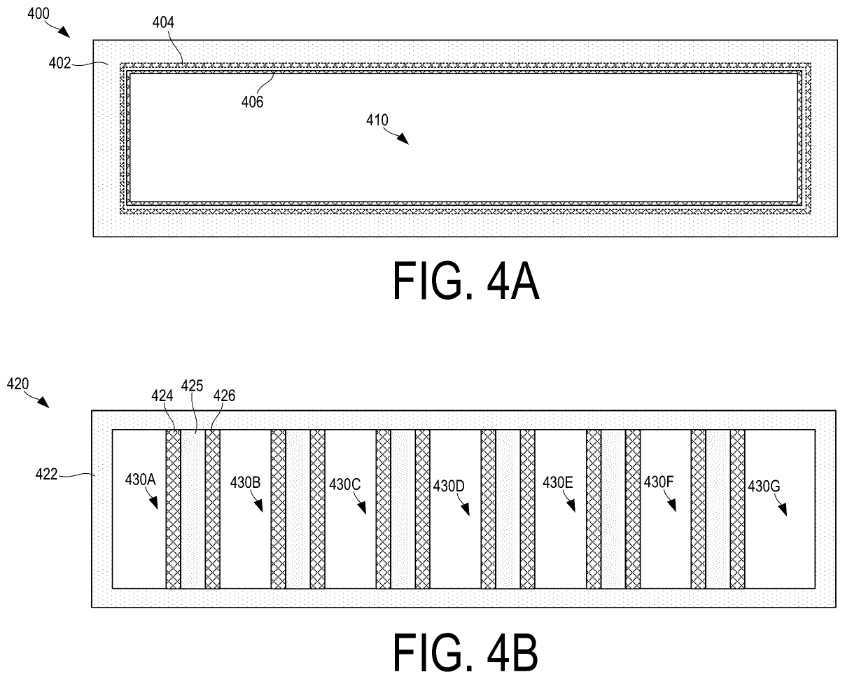

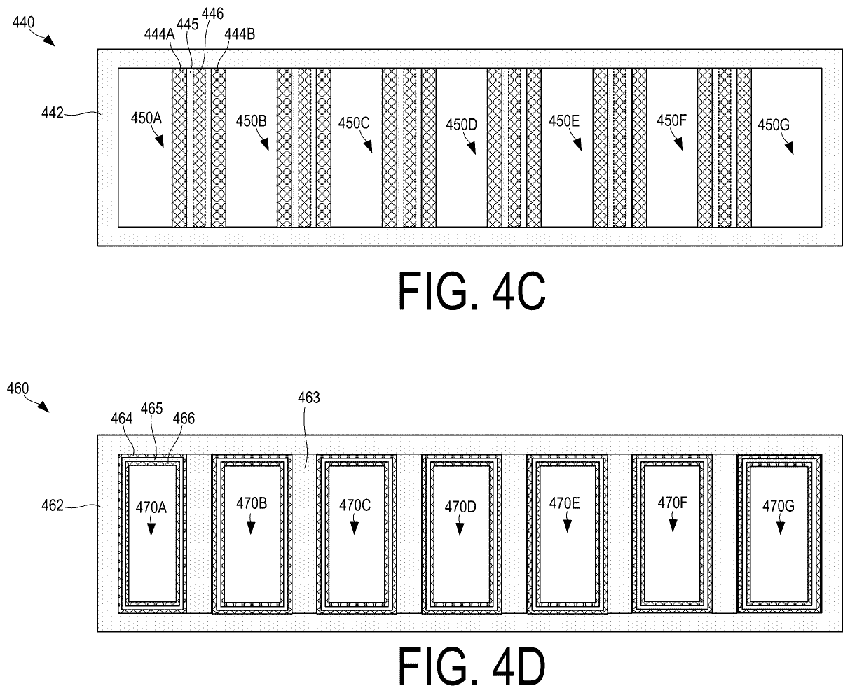

FIGS. 4A-4D illustrate other example AC ionic blower apparatuses 400, 420, 440, 460 in accordance with embodiments herein. The example apparatus 400 of FIG. 4A is substantially similar to the apparatus 200 of FIGS. 2A-2C, but with the electrode 404 being embedded within the housing 402 as described above. The material of the housing 402 may thus serve as the dielectric layer between the electrodes 404, 406, the latter of which is on the inside surface of the housing 402 that defines the hole 410.

The example apparatus 420 of FIG. 4B includes a housing 422 similar to the housing 202 of the example apparatus 200, and further includes a plurality of dielectric pillars 425 formed therein. The apparatus 420 includes electrode structures that are formed around the dielectric pillars 425, with electrodes 424, 426 on either side of each pillar 425 as shown. The electrodes 424, 426 are offset in the same manner as described above (i.e., one of the electrodes is closer to the viewer while the other is further into the page in the example shown), causing air to flow through the plurality of holes 430 formed inside the housing 422. In the example shown, the housing 422 and pillars 425 may be the same or different materials.

The example apparatus 440 of FIG. 4C includes a housing 442 similar to the housing 202 of the example apparatus 200 (and housing 442), and further includes a plurality of dielectric pillars 445 formed therein. The apparatus 450 includes electrode structures that are formed around the dielectric pillars 445, with electrodes 444A, 444B on either side of each pillar 445 as shown, with an electrode 446 embedded within the dielectric pillar 445. The electrodes 444A, 444B are offset with respect to the embedded electrode 446 in the same manner as described above (i.e., the electrodes 444 are closer to the viewer while the embedded electrode 446 is further into the page), causing air to flow through the plurality of holes 450 formed inside the housing 442. In the example shown, the housing 442 and pillars 445 may be the same or different materials.

The example apparatus 460 of FIG. 4D includes a housing 462 similar to the housing 202 of the example apparatus 200, and further includes a plurality of pillars 463 formed therein (similar to the pillar structure of the apparatus 420 of FIG. 4B). The apparatus 460 includes electrode structures that are formed in the same manner as the apparatus 200, but with each electrode structure being formed within a separate hole 470 of the apparatus 460 and defined by the pillars. The electrodes 464, 466 are offset in the same manner as described above (i.e., one of the electrodes is closer to the viewer while the other is further into the page in the example shown), causing air to flow through the plurality of holes 470.

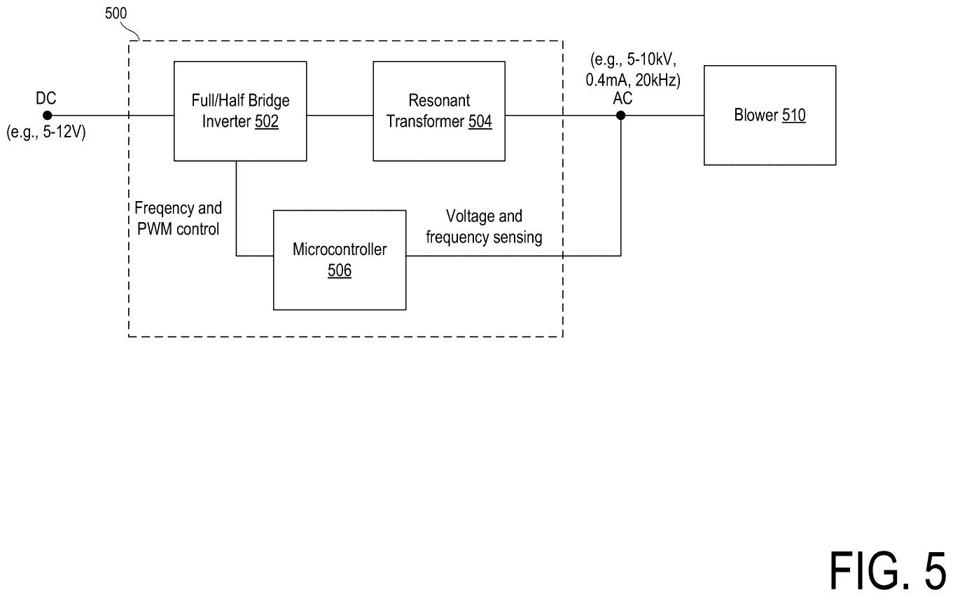

FIG. 5 illustrates a block diagram of example driving circuitry for an AC ionic blower in accordance with embodiments herein. In most computing platforms in which an AC ionic blower apparatus may be implemented (e.g., inside a laptop), a DC-AC converter may be needed to convert from a typical 5-12V DC signal available within the computing circuitry to a high voltage AC signal, e.g., a 5-10 kV, 20-50 kHz signal, needed to drive the blower.

The example driver circuit 500 of FIG. 5 includes a full or half bridge inverter 502, converts the input DC voltage to a square wave. The square wave from the bridge inverter 502 is then fed to a resonant transformer 504, which outputs an AC voltage that is supplied to an AC ionic blower 510 as described herein. The ionic wind device acts as capacitor, which, along with the transformer secondary, acts as an LCR series resonant circuit. This resonance may provide even higher voltage amplification than possible with just the transformer alone. The resonant circuit also helps to transform the square wave output from primary side excitation to sine wave, hence reducing the harmonics associated as well. The circuit 500 also includes a microcontroller 506 connected between the AC output of the transformer 504 and the bridge inverter 502 that can be used to control the speed of the blower 510. The microcontroller 506 may control the speed by frequency and/or pulse width modulation (PWM). The design of the circuit 500 may be implemented with known components on a circuit board having an area of 40 mm×17 mm or smaller, allowing it to be implemented in a thin computing device such as a laptop device.

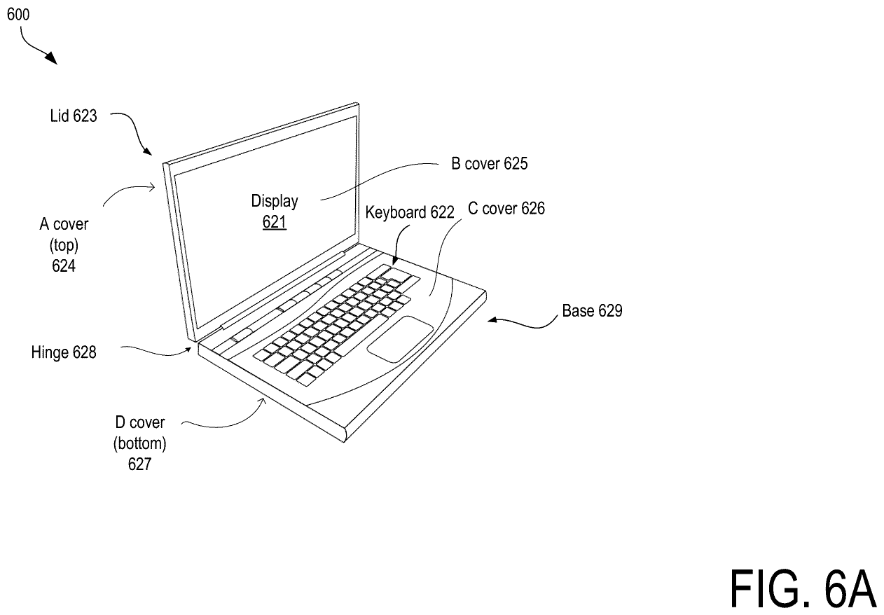

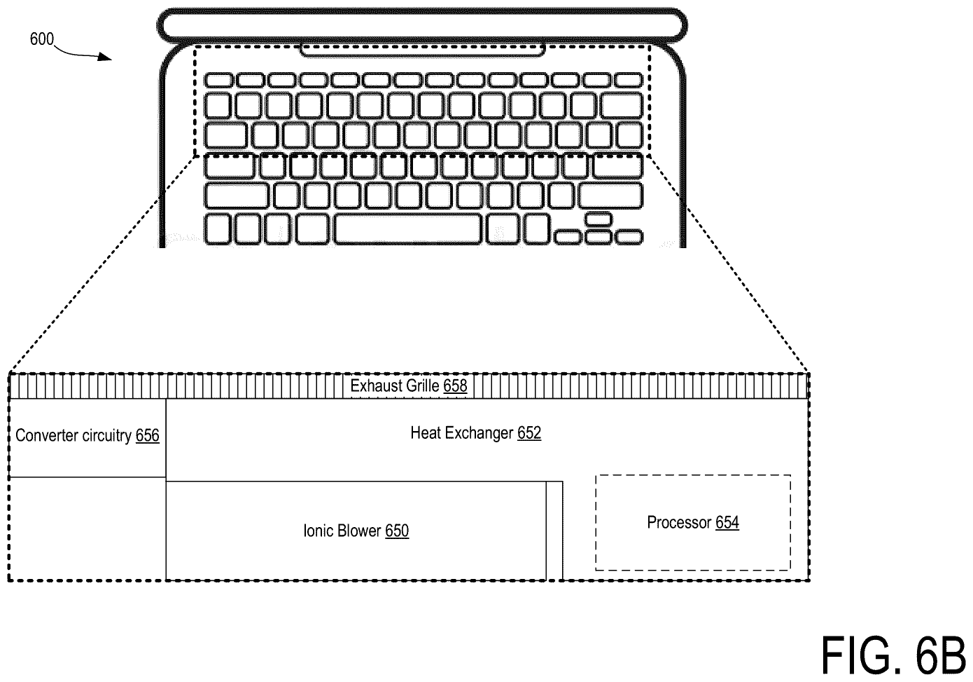

FIGS. 6A-6B illustrate an example computing device 600 in which aspects of the present disclosure may be incorporated. The computing device 600 can be a laptop (as shown) or another type of mobile computing device with a similar form factor, such as a foldable tablet or smartphone. In some instances, aspects of present disclosure may be incorporated into a free-standing display monitor with a user-facing camera, which may be connected to a computing device that controls the display and camera.

As shown in FIG. 6A, the computing device 600 includes a housing, which includes a lid 623 with an A cover 624 that is a “world-facing” surface of the lid 623 when the computing device 600 is in a closed configuration and a B cover 625 that comprises a user-facing display 621 when the lid 623 is open (e.g., as shown). The computing device 600 also includes a base 629 with a C cover 626 that includes a keyboard 622 that is upward facing when the device 600 is an open configuration (e.g., as shown) and a D cover 627 that forms the bottom of the base 629. In some embodiments, the base 629 includes the primary computing resources (e.g., host processor unit(s), graphics processing unit (GPU)) of the device 600, along with a battery, memory, and storage, and communicates with the lid 623 via wires that pass through a hinge 628 that connects the base 629 with the lid 623. In some embodiments, the computing device 600 can be a dual display device with a second display comprising a portion of the C cover 626. For example, in some embodiments, an “always-on” display (AOD) can occupy a region of the C cover below the keyboard that is visible when the lid 623 is closed. In other embodiments, a second display covers most of the surface of the C cover and a removable keyboard can be placed over the second display or the second display can present a virtual keyboard to allow for keyboard input.

As shown in FIG. 6B, an AC ionic blower 650 (which may be implemented in any way described herein) may be fit within a “forehead” area of the C-cover 626. In the example shown, the device 600 includes a heat exchanger 652 (e.g., a heat pipe device, vapor chamber device, or other type of cooling device) coupled to a processor 654. The blower 650 is arranged adjacent to the heat exchanger 652 so that the blower 650 can provide air flow past the heat exchanger 652 and out the exhaust grille 658 to further aid in cooling of the processor 654, similar to a typical fan-based apparatus. As shown, the device 600 further includes converter circuitry 656 for the blower 650, which may be implemented in the same or similar manner as described above with respect to FIG. 5. Although shown as being in the forehead area of the C-cover, it will be understood that the blower 650 (and other components shown) may be implemented in other areas of the device 600. For example, the blower 650 and heat exchanger 652 may be implemented at other inlet areas of the device 600, e.g., a back or side inlet/outlet grille of the C-cover of the device 600.

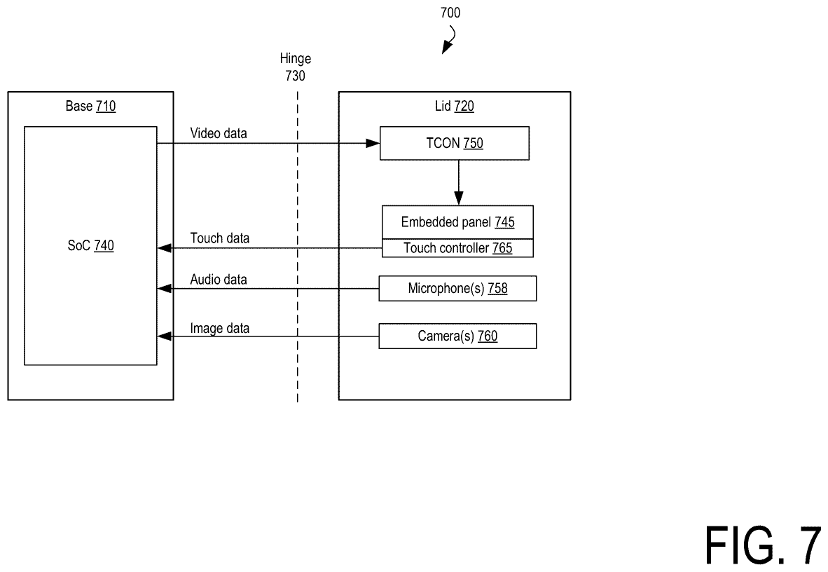

FIG. 7 illustrates an example block diagram of a computing device in which aspects of the present disclosure may be incorporated. The computing device 700 comprises a base 710 connected to a lid 720 by a hinge 730. The mobile computing device (also referred to herein as “user device”) 700 can be a laptop or a mobile computing device with a similar form factor. The base 710 comprises a host system-on-a-chip (SoC) 740 that comprises one or more processor units integrated with one or more additional components, such as a memory controller, graphics processing unit (GPU), caches, an image processing module, and other components described herein. The base 710 can further comprise a physical keyboard, touchpad, battery, memory, storage, and external ports. The lid 720 comprises an embedded display panel 745, a timing controller (TCON) 750, one or more microphones 758, one or more cameras 760, and a touch controller 765. The TCON 750 converts video data 790 received from the SoC 740 into signals that drive the display panel 745.

The display panel 745 can be any type of embedded display in which the display elements responsible for generating light or allowing the transmission of light are located in each pixel. Such displays may include TFT LCD (thin-film-transistor liquid crystal display), micro-LED (micro-light-emitting diode (LED)), OLED (organic LED), and QLED (quantum dot LED) displays. The display panel 745 can comprise a touchscreen comprising one or more dedicated layers for implementing touch capabilities or ‘in-cell’ or ‘on-cell’ touchscreen technologies that do not require dedicated touchscreen layers. A touch controller 765 drives touchscreen technology utilized in the display panel 745 and collects touch sensor data provided by the employed touchscreen technology. The microphones 758 can comprise microphones located in the bezel of the lid or in-display microphones located in the display area, the region of the panel that displays content. The one or more cameras 760 can similarly comprise cameras located in the bezel or in-display cameras located in the display area.

The hinge 730 can be any physical hinge that allows the base 710 and the lid 720 to be rotatably connected. The wires that pass across the hinge 730 comprise wires for passing video data from the SoC 740 to the TCON 750, wires for passing audio data between the microphones 758 and the SoC 740, wires for providing image data from the cameras 760 to the SoC 740, and wires for providing touch data from the touch controller 765 to the SoC 740. In some embodiments, data shown as being passed over different sets of wires between the SoC and various components are communicated over the same set of wires. For example, in some embodiments, all of the different types of data shown can be sent over a single PCIe-based or USB-based data bus. In some embodiments, the lid 720 is removably attachable to the base 710. In some embodiments, the hinge can allow the base 710 and the lid 720 to rotate to substantially 360 degrees with respect to each other.

The components illustrated in FIG. 7 as being located in the base of a mobile computing device can be located in a base housing (e.g., base 629 of the device 600) and components illustrated in FIG. 7 as being located in the lid of a mobile computing device can be located in a lid housing (e.g., lid 623 of the device 600).

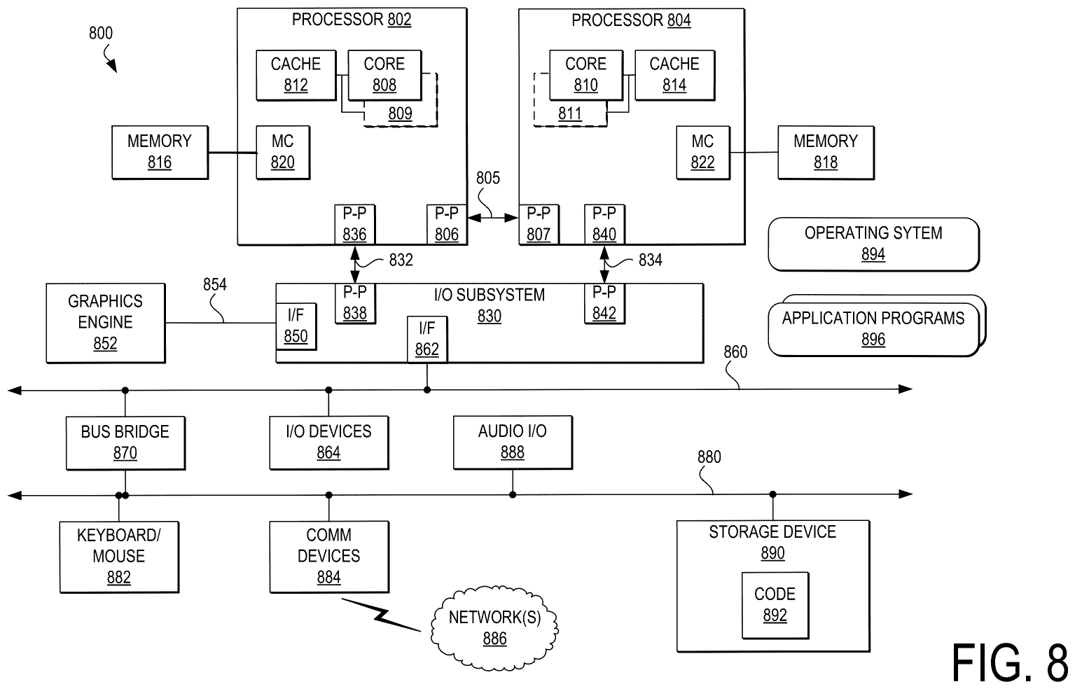

FIG. 8 is a block diagram of computing device components which may be included in a mobile computing device incorporating aspects of the present disclosure. In some embodiments, the components shown may be implemented within the SoC 740 of FIG. 7, for instance. Generally, components shown in FIG. 8 can communicate with other shown components, including those in a lid controller hub, although not all connections are shown, for ease of illustration. The components 800 comprise a multiprocessor system comprising a first processor 802 and a second processor 804 and is illustrated as comprising point-to-point (P-P) interconnects. For example, a point-to-point (P-P) interface 806 of the processor 802 is coupled to a point-to-point interface 807 of the processor 804 via a point-to-point interconnection 805. It is to be understood that any or all of the point-to-point interconnects illustrated in FIG. 8 can be alternatively implemented as a multi-drop bus, and that any or all buses illustrated in FIG. 8 could be replaced by point-to-point interconnects.

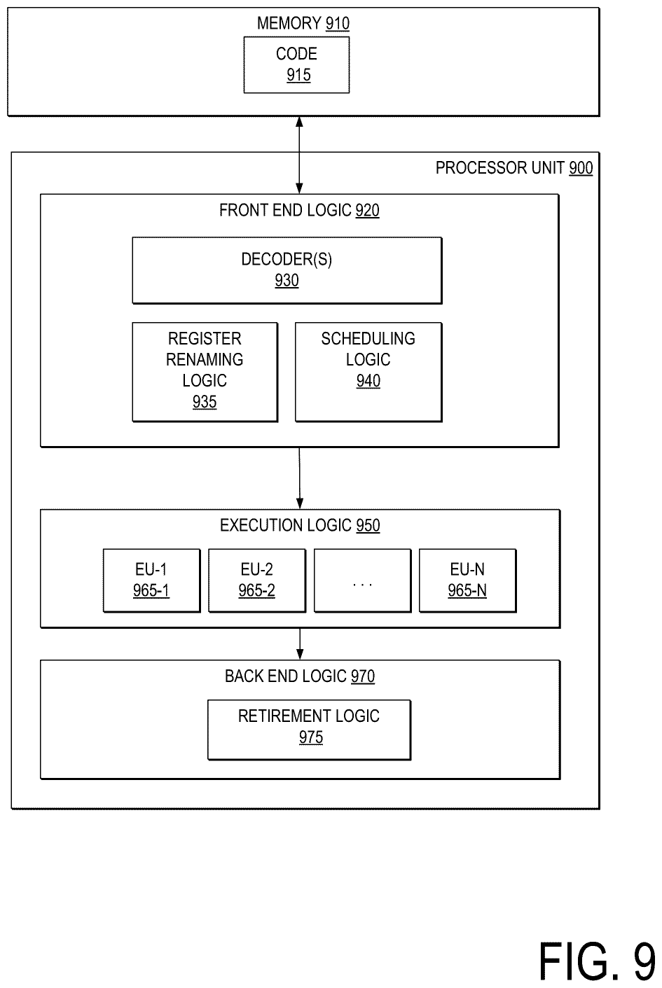

As shown in FIG. 8, the processors 802 and 804 are multicore processors. Processor 802 comprises processor cores 808 and 809, and processor 804 comprises processor cores 810 and 811. Processor cores 808-811 can execute computer-executable instructions in a manner similar to that discussed below in connection with FIG. 9, or in other manners.

Processors 802 and 804 further comprise at least one shared cache memory 812 and 814, respectively. The shared caches 812 and 814 can store data (e.g., instructions) utilized by one or more components of the processor, such as the processor cores 808-809 and 810-811. The shared caches 812 and 814 can be part of a memory hierarchy for the device. For example, the shared cache 812 can locally store data that is also stored in a memory 816 to allow for faster access to the data by components of the processor 802. In some embodiments, the shared caches 812 and 814 can comprise multiple cache layers, such as level 1 (L1), level 2 (L2), level 3 (L3), level 4 (L4), and/or other caches or cache layers, such as a last level cache (LLC).

Although two processors are shown, the device can comprise any number of processors or other compute resources, including those in a lid controller hub. Further, a processor can comprise any number of processor cores. A processor can take various forms such as a central processing unit, a controller, a graphics processor, an accelerator (such as a graphics accelerator, digital signal processor (DSP), or artificial intelligence (AI) accelerator)). A processor in a device can be the same as or different from other processors in the device. In some embodiments, the device can comprise one or more processors that are heterogeneous or asymmetric to a first processor, accelerator, field programmable gate array (FPGA), or any other processor. There can be a variety of differences between the processing elements in a system in terms of a spectrum of metrics of merit including architectural, microarchitectural, thermal, power consumption characteristics and the like. These differences can effectively manifest themselves as asymmetry and heterogeneity amongst the processors in a system. In some embodiments, the processors 802 and 804 reside in a multi-chip package. As used herein, the terms “processor unit” and “processing unit” can refer to any processor, processor core, component, module, engine, circuitry or any other processing element described herein. A processor unit or processing unit can be implemented in hardware, software, firmware, or any combination thereof capable of. A lid controller hub can comprise one or more processor units.

Processors 802 and 804 further comprise memory controller logic (MC) 820 and 822. As shown in FIG. 8, MCs 820 and 822 control memories 816 and 818 coupled to the processors 802 and 804, respectively. The memories 816 and 818 can comprise various types of memories, such as volatile memory (e.g., dynamic random-access memories (DRAM), static random-access memory (SRAM)) or non-volatile memory (e.g., flash memory, solid-state drives, chalcogenide-based phase-change non-volatile memories). While MCs 820 and 822 are illustrated as being integrated into the processors 802 and 804, in alternative embodiments, the MCs can be logic external to a processor, and can comprise one or more layers of a memory hierarchy.

Processors 802 and 804 are coupled to an Input/Output (I/O) subsystem 830 via P-P interconnections 832 and 834. The point-to-point interconnection 832 connects a point-to-point interface 836 of the processor 802 with a point-to-point interface 838 of the I/O subsystem 830, and the point-to-point interconnection 834 connects a point-to-point interface 840 of the processor 804 with a point-to-point interface 842 of the I/O subsystem 830. Input/Output subsystem 830 further includes an interface 850 to couple I/O subsystem 830 to a graphics module 852, which can be a high-performance graphics module. The I/O subsystem 830 and the graphics module 852 are coupled via a bus 854. Alternately, the bus 854 could be a point-to-point interconnection.

Input/Output subsystem 830 is further coupled to a first bus 860 via an interface 862. The first bus 860 can be a Peripheral Component Interconnect (PCI) bus, a PCI Express (PCIe) bus, another third generation I/O (input/output) interconnection bus or any other type of bus.

Various I/O devices 864 can be coupled to the first bus 860. A bus bridge 870 can couple the first bus 860 to a second bus 880. In some embodiments, the second bus 880 can be a low pin count (LPC) bus. Various devices can be coupled to the second bus 880 including, for example, a keyboard/mouse 882, audio I/O devices 888 and a storage device 890, such as a hard disk drive, solid-state drive or other storage device for storing computer-executable instructions (code) 892. The code 892 can comprise computer-executable instructions for performing technologies described herein. Additional components that can be coupled to the second bus 880 include communication device(s) or components 884, which can provide for communication between the device and one or more wired or wireless networks 886 (e.g. Wi-Fi, cellular or satellite networks) via one or more wired or wireless communication links (e.g., wire, cable, Ethernet connection, radio-frequency (RF) channel, infrared channel, Wi-Fi channel) using one or more communication standards (e.g., IEEE 802.11 standard and its supplements).

The device can comprise removable memory such as flash memory cards (e.g., SD (Secure Digital) cards), memory sticks, Subscriber Identity Module (SIM) cards). The memory in the computing device (including caches 812 and 814, memories 816 and 818 and storage device 890, and memories in the lid controller hub) can store data and/or computer-executable instructions for executing an operating system 894, or application programs 896. Example data includes web pages, text messages, images, sound files, video data, sensor data or any other data received from a lid controller hub, or other data sets to be sent to and/or received from one or more network servers or other devices by the device via one or more wired or wireless networks, or for use by the device. The device can also have access to external memory (not shown) such as external hard drives or cloud-based storage.

The operating system 894 can control the allocation and usage of the components illustrated in FIG. 8 and support one or more application programs 896. The application programs 896 can include common mobile computing device applications (e.g., email applications, calendars, contact managers, web browsers, messaging applications) as well as other computing applications.

The device can support various input devices, such as a touchscreen, microphones, cameras (monoscopic or stereoscopic), trackball, touchpad, trackpad, mouse, keyboard, proximity sensor, light sensor, pressure sensor, infrared sensor, electrocardiogram (ECG) sensor, PPG (photoplethysmogram) sensor, galvanic skin response sensor, and one or more output devices, such as one or more speakers or displays. Any of the input or output devices can be internal to, external to or removably attachable with the device. External input and output devices can communicate with the device via wired or wireless connections.

In addition, the computing device can provide one or more natural user interfaces (NUIs). For example, the operating system 894, application programs 896, or a lid controller hub can comprise speech recognition as part of a voice user interface that allows a user to operate the device via voice commands. Further, the device can comprise input devices and components that allows a user to interact with the device via body, hand, or face gestures.

The device can further comprise one or more communication components 884. The components 884 can comprise wireless communication components coupled to one or more antennas to support communication between the device and external devices. Antennas can be located in a base, lid, or other portion of the device. The wireless communication components can support various wireless communication protocols and technologies such as Near Field Communication (NFC), IEEE 1002.11 (Wi-Fi) variants, WiMax, Bluetooth, Zigbee, 4G Long Term Evolution (LTE), Code Division Multiplexing Access (CDMA), Universal Mobile Telecommunication System (UMTS) and Global System for Mobile Telecommunication (GSM). In addition, the wireless modems can support communication with one or more cellular networks for data and voice communications within a single cellular network, between cellular networks, or between the mobile computing device and a public switched telephone network (PSTN).

The device can further include at least one input/output port (which can be, for example, a USB, IEEE 1394 (FireWire), Ethernet and/or RS-232 port) comprising physical connectors; a power supply (such as a rechargeable battery); a satellite navigation system receiver, such as a GPS receiver; a gyroscope; an accelerometer; and a compass. A GPS receiver can be coupled to a GPS antenna. The device can further include one or more additional antennas coupled to one or more additional receivers, transmitters and/or transceivers to enable additional functions.

FIG. 8 illustrates one example computing device architecture. Computing devices based on alternative architectures can be used to implement technologies described herein. For example, instead of the processors 802 and 804, and the graphics module 852 being located on discrete integrated circuits, a computing device can comprise a SoC (system-on-a-chip) integrated circuit incorporating one or more of the components illustrated in FIG. 8. In one example, an SoC can comprise multiple processor cores, cache memory, a display driver, a GPU, multiple I/O controllers, an AI accelerator, an image processing unit driver, I/O controllers, an AI accelerator, an image processor unit. Further, a computing device can connect elements via bus or point-to-point configurations different from that shown in FIG. 8. Moreover, the illustrated components in FIG. 8 are not required or all-inclusive, as shown components can be removed and other components added in alternative embodiments.

FIG. 9 is a block diagram of an example processor unit 900 to execute computer-executable instructions. The processor unit 900 can be any type of processor or processor core, such as a microprocessor, an embedded processor, a digital signal processor (DSP), network processor, or accelerator. The processor unit 900 can be a single-threaded core or a multithreaded core in that it may include more than one hardware thread context (or “logical processor”) per core.

FIG. 9 also illustrates a memory 910 coupled to the processor 900. The memory 910 can be any memory described herein or any other memory known to those of skill in the art. The memory 910 can store computer-executable instructions 915 (code) executable by the processor unit 900.

The processor core comprises front-end logic 920 that receives instructions from the memory 910. An instruction can be processed by one or more decoders 930. The decoder 930 can generate as its output a micro operation such as a fixed width micro operation in a predefined format, or generate other instructions, microinstructions, or control signals, which reflect the original code instruction. The front-end logic 920 further comprises register renaming logic 935 and scheduling logic 940, which generally allocate resources and queues operations corresponding to converting an instruction for execution.

The processor unit 900 further comprises execution logic 950, which comprises one or more execution units (EUs) 965-1 through 965-N. Some processor core embodiments can include a number of execution units dedicated to specific functions or sets of functions. Other embodiments can include only one execution unit or one execution unit that can perform a particular function. The execution logic 950 performs the operations specified by code instructions. After completion of execution of the operations specified by the code instructions, back end logic 970 retires instructions using retirement logic 975. In some embodiments, the processor unit 900 allows out of order execution but requires in-order retirement of instructions. Retirement logic 975 can take a variety of forms as known to those of skill in the art (e.g., re-order buffers or the like).

The processor unit 900 is transformed during execution of instructions, at least in terms of the output generated by the decoder 930, hardware registers and tables utilized by the register renaming logic 935, and any registers (not shown) modified by the execution logic 950. Although not illustrated in FIG. 9, a processor can include other elements on an integrated chip with the processor unit 900. For example, a processor may include additional elements such as memory control logic, one or more graphics modules, I/O control logic modules and/or one or more caches.

As used in any embodiment herein, the term “module” refers to logic that may be implemented in a hardware component or device, software or firmware running on a processor, or a combination thereof, to perform one or more operations consistent with the present disclosure. Software may be embodied as a software package, code, instructions, instruction sets and/or data recorded on non-transitory computer-readable storage mediums. Firmware may be embodied as code, instructions or instruction sets and/or data that are hard-coded (e.g., nonvolatile) in memory devices. As used in any embodiment herein, the term “circuitry” can comprise, for example, singly or in any combination, hardwired circuitry, programmable circuitry such as computer processors comprising one or more individual instruction processing cores, state machine circuitry, and/or firmware that stores instructions executed by programmable circuitry. Modules described herein may, collectively or individually, be embodied as circuitry that forms a part of one or more devices. Thus, any of the modules can be implemented as circuitry, such as continuous itemset generation circuitry, entropy-based discretization circuitry, etc. A computer device referred to as being programmed to perform a method can be programmed to perform the method via software, hardware, firmware or combinations thereof.

The use of reference numbers in the claims and the specification is meant as in aid in understanding the claims and the specification and is not meant to be limiting.

Any of the disclosed methods can be implemented as computer-executable instructions or a computer program product. Such instructions can cause a computer or one or more processors capable of executing computer-executable instructions to perform any of the disclosed methods. Generally, as used herein, the term “computer” refers to any computing device or system described or mentioned herein, or any other computing device. Thus, the term “computer-executable instruction” refers to instructions that can be executed by any computing device described or mentioned herein, or any other computing device.

The computer-executable instructions or computer program products as well as any data created and used during implementation of the disclosed technologies can be stored on one or more tangible or non-transitory computer-readable storage media, such as optical media discs (e.g., DVDs, CDs), volatile memory components (e.g., DRAM, SRAM), or non-volatile memory components (e.g., flash memory, solid state drives, chalcogenide-based phase-change non-volatile memories). Computer-readable storage media can be contained in computer-readable storage devices such as solid-state drives, USB flash drives, and memory modules. Alternatively, the computer-executable instructions may be performed by specific hardware components that contain hardwired logic for performing all or a portion of disclosed methods, or by any combination of computer-readable storage media and hardware components.

The computer-executable instructions can be part of, for example, a dedicated software application or a software application that is accessed via a web browser or other software application (such as a remote computing application). Such software can be read and executed by, for example, a single computing device or in a network environment using one or more networked computers. Further, it is to be understood that the disclosed technology is not limited to any specific computer language or program. For instance, the disclosed technologies can be implemented by software written in C++, Java, Perl, Python, JavaScript, Adobe Flash, or any other suitable programming language. Likewise, the disclosed technologies are not limited to any particular computer or type of hardware.

Furthermore, any of the software-based embodiments (comprising, for example, computer-executable instructions for causing a computer to perform any of the disclosed methods) can be uploaded, downloaded or remotely accessed through a suitable communication means. Such suitable communication means include, for example, the Internet, the World Wide Web, an intranet, cable (including fiber optic cable), magnetic communications, electromagnetic communications (including RF, microwave, and infrared communications), electronic communications, or other such communication means.

As used in this application and in the claims, a list of items joined by the term “and/or” can mean any combination of the listed items. For example, the phrase “A, B and/or C” can mean A; B; C; A and B; A and C; B and C; or A, B, and C. Further, as used in this application and in the claims, a list of items joined by the term “at least one of” can mean any combination of the listed terms. For example, the phrase “at least one of A, B, or C” can mean A; B; C; A and B; A and C; B and C; or A, B, and C. Moreover, as used in this application and in the claims, a list of items joined by the term “one or more of” can mean any combination of the listed terms. For example, the phrase “one or more of A, B and C” can mean A; B; C; A and B; A and C; B and C; or A, B, and C.

The disclosed methods, apparatuses and systems are not to be construed as limiting in any way. Instead, the present disclosure is directed toward all novel and nonobvious features and aspects of the various disclosed embodiments, alone and in various combinations and subcombinations with one another. The disclosed methods, apparatuses, and systems are not limited to any specific aspect or feature or combination thereof, nor do the disclosed embodiments require that any one or more specific advantages be present or problems be solved.

Although the operations of some of the disclosed methods are described in a particular, sequential order for convenient presentation, it is to be understood that this manner of description encompasses rearrangement, unless a particular ordering is required by specific language set forth herein. For example, operations described sequentially may in some cases be rearranged or performed concurrently. Moreover, for the sake of simplicity, the attached figures may not show the various ways in which the disclosed methods can be used in conjunction with other methods.

Certain non-limiting examples of the presently described techniques are provided below. Each of the following non-limiting examples may stand on its own or may be combined in any permutation or combination with any one or more of the other examples provided below or throughout the present disclosure.
Example 1 is an apparatus comprising: a housing defining a hole through the housing; a first electrode formed around the hole; a second electrode formed around the hole, a center of the second electrode offset from a center of the first electrode; and a dielectric material between the first electrode and the second electrode.
Example 2 includes the subject matter of Example 1, wherein the first electrode is on one or more surfaces defining the hole through the housing.
Example 3 includes the subject matter of Example 1, wherein the first electrode is embedded in the housing and the dielectric material is integral with the housing.
Example 4 includes the subject matter of Example 1, wherein the hole is a first hole, the dielectric material is a first dielectric material, and the housing further defines a second hole through the housing in the same direction as the first hole, the apparatus further comprising: a third electrode formed around the second hole; a fourth electrode formed around the second hole, a center of the fourth electrode offset from a center of the third electrode; and a second dielectric material between the third electrode and the fourth electrode.
Example 5 includes the subject matter of Example 4, wherein the third electrode is on one or more surfaces defining the second hole.
Example 6 includes the subject matter of Example 4, wherein the third electrode is embedded in the housing and the second dielectric material is integral with the housing.
Example 7 includes the subject matter of any one of Examples 1-6, wherein the first electrode or the second electrode have a rectangular shape.
Example 8 includes the subject matter of any one of Examples 1-7, wherein the first electrode or the second electrode have a saw tooth shape.
Example 9 includes the subject matter of any one of Examples 1-8, wherein the second electrode is exposed within the hole.
Example 10 is an apparatus comprising: a housing; a dielectric material defining a first hole and a second hole the housing; a first electrode formed on a first side of the dielectric material; and a second electrode formed on a second side of the dielectric material opposite the first side, a center of the second electrode offset from a center of the first electrode.
Example 11 includes the subject matter of Example 10, wherein the first electrode is in the first hole and the second electrode is in the second hole.
Example 12 includes the subject matter of Example 10 or 11, wherein the housing is rectangular, and the dielectric material is between a first side defining a length of the rectangular housing and a second side defining the length of the rectangular housing.
Example 13 includes the subject matter of any one of Examples 10-12, wherein the housing defines a third hole, the dielectric material is a first dielectric material, and the apparatus further comprises: a second dielectric material defining the second hole and a third hole in the housing, the second dielectric material parallel with the first dielectric material; a third electrode formed on a first side of the second dielectric material; and a fourth electrode formed on a second side of the second dielectric material opposite the first side, a center of the third electrode offset from a center of the fourth electrode
Example 14 includes the subject matter of any one of Examples 10-13, wherein the first electrode or the second electrode have a rectangular shape.
Example 15 includes the subject matter of any one of Examples 10-14, wherein the first electrode or the second electrode have a saw tooth shape.
Example 16 is a computing device comprising: a processor; a heat exchanger coupled to the processor; a blower apparatus arranged to cause airflow over the heat exchanger, the blower apparatus according to any one of Examples 1-15.
Example 17 includes the subject matter of Example 16, further comprising power supply circuitry to provide an alternating current (AC) signal to the blower apparatus.
Example 18 includes the subject matter of Example 17, wherein the power supply circuitry comprises direct current (DC)-to-AC conversion circuitry comprising a full or half bridge inverter to convert a DC signal to a square wave, a transformer to output (e.g., amplify) an AC signal (e.g., higher voltage than the input) based on the square wave output by the inverter.
Example 19 includes the subject matter of Example 18, wherein the DC-AC conversion circuitry further comprises a microcontroller to control the full or half bridge inverter using frequency or pulse width modulation.
Example 20 includes the subject matter of Example 18, wherein the AC signal is between 5-10 kV and between 20-50 kHz.
Example 21 includes an apparatus comprising: a housing; a dielectric material defining a first hole and a second hole the housing; a first electrode formed on a first side of the dielectric material; and a second electrode formed on a second side of the dielectric material opposite the first side; and a third electrode within the dielectric material, a center of the third electrode offset from a center of the first electrode and a center of the second electrode.
Example 22 includes the subject matter of Example 21, wherein the first electrode is in the first hole and the second electrode is in the second hole.
Example 23 includes the subject matter of Example 21 or 22, wherein the dielectric material is a first dielectric material, and the apparatus further comprises: a second dielectric material defining the second hole and a third hole in the housing, the second dielectric material parallel with the first dielectric material; a fourth electrode formed on a first side of the second dielectric material; and a fifth electrode formed on a second side of the second dielectric material opposite the first side; and a sixth electrode within the second dielectric material, a center of the sixth electrode offset from a center of the fourth electrode and a center of the fifth electrode.
Example 24 includes the subject matter of any one of Examples 21-23, wherein the first electrode or the second electrode have a rectangular shape.
Example 25 includes the subject matter of any one of Examples 21-23, wherein the first electrode or the second electrode have a saw tooth shape.

1. An apparatus comprising:
a housing defining a hole through the housing;
a first electrode formed around the hole;
a second electrode formed around the hole, a center of the second electrode offset from a center of the first electrode; and
a dielectric material between the first electrode and the second electrode.

2. The apparatus of claim 1, wherein the first electrode is on one or more surfaces defining the hole through the housing.

3. The apparatus of claim 1, wherein the first electrode is embedded in the housing and the dielectric material is integral with the housing.

4. The apparatus of claim 1, wherein the hole is a first hole, the dielectric material is a first dielectric material, and the housing further defines a second hole through the housing in a same direction as the first hole, the apparatus further comprising:
a third electrode formed around the second hole;
a fourth electrode formed around the second hole, a center of the fourth electrode offset from a center of the third electrode; and
a second dielectric material between the third electrode and the fourth electrode.

5. The apparatus of claim 4, wherein the third electrode is on one or more surfaces defining the second hole.

6. The apparatus of claim 4, wherein the third electrode is embedded in the housing and the second dielectric material is integral with the housing.

7. The apparatus of claim 1, wherein the first electrode or the second electrode have a rectangular shape.

8. The apparatus of claim 1, wherein the first electrode or the second electrode have a saw tooth shape.

9. The apparatus of claim 1, wherein the second electrode is exposed within the hole.

10. An apparatus comprising:
a housing;
a dielectric material defining a first hole and a second hole the housing;
a first electrode formed on a first side of the dielectric material; and
a second electrode formed on a second side of the dielectric material opposite the first side, a center of the second electrode offset from a center of the first electrode.

11. The apparatus of claim 10, wherein the first electrode is in the first hole and the second electrode is in the second hole.

12. The apparatus of claim 10, wherein the housing is rectangular, and the dielectric material is between a first side defining a length of the rectangular housing and a second side defining the length of the rectangular housing.

13. The apparatus of claim 10, wherein the dielectric material is a first dielectric material, and the apparatus further comprises:
a second dielectric material defining the second hole and a third hole in the housing, the second dielectric material parallel with the first dielectric material;
a third electrode formed on a first side of the second dielectric material; and
a fourth electrode formed on a second side of the second dielectric material opposite the first side, a center of the third electrode offset from a center of the fourth electrode.

14. The apparatus of claim 10, wherein the first electrode or the second electrode have a rectangular shape.

15. The apparatus of claim 10, wherein the first electrode or the second electrode have a saw tooth shape.

16. A computing device comprising:
a processor;
a heat exchanger coupled to the processor;
a blower apparatus arranged to cause airflow over the heat exchanger, the blower apparatus comprising:
a first electrode around a hole within the blower apparatus;
a second electrode around the hole, a center of the second electrode offset from a center of the first electrode, the second electrode exposed within the hole; and
a dielectric material between the first electrode and the second electrode.

17. The computing device of claim 16, further comprising power supply circuitry to provide an alternating current (AC) signal to the blower apparatus.

18. The computing device of claim 17, wherein the power supply circuitry comprises direct current (DC)-to-AC conversion circuitry comprising a full or half bridge inverter to convert a DC signal to a square wave, a transformer to output an AC signal based on the square wave output by the inverter.

19. The computing device of claim 18, wherein the DC-to-AC conversion circuitry further comprises a microcontroller to control the full or half bridge inverter using frequency or pulse width modulation.

20. The computing device of claim 18, wherein the AC signal is between 5-10 kV and between 20-50 kHz.
